(19) United States
(12) Patent Application Publication
(10) Pub. No.: US 2026/0188605 A1
(43) Pub. Date: Jul. 2, 2026

(54) CHARGED PARTICLE BEAM DEVICE AND INSPECTION METHOD USING SAME

(71) Applicant: Hitachi High-Tech Corporation, Minato-ku, Tokyo (JP)

(72) Inventors: Naho TERAO, Tokyo (JP); Toshiyuki YOKOSUKA, Tokyo (JP); Tomohito NAKANO, Tokyo (JP); Hajime KAWANO, Tokyo (JP)

(73) Assignee: Hitachi High-Tech Corporation, Minato-ku, Tokyo (JP)

(21) Appl. No.: 18/729,623

(22) PCT Filed: Jan. 19, 2022
(86) PCT No.: PCT/JP2022/001684

§ 371 Date: Jul. 17, 2024

(51) Int. Cl. H01J 37/147; H01J 37/22; H01J 37/244; H01J 37/256; H01J 37/28

(52) U.S. Cl. CPC H01J 37/1474; H01J 37/222; H01J 37/244; H01J 37/256; H01J 37/28; H01J 2237/0048; H01J 2237/057; H01J 2237/221; H01J 2237/2817

(57) ABSTRACT

The present invention provides a charged particle beam device capable of suppressing the influence of charging of a sample on electron trajectories, and achieving both high accuracy and high throughput. This charged particle beam device is characterized by comprising: a scanning deflector that scans an electron beam emitted from a charged particle source; a signal electron deflector that deflects the trajectories of signal electrons emitted from a sample; a plurality of detectors that detect signal electrons obtained on the basis of the electron beam scanning; and a computing unit that creates an image of the sample using the signal electrons detected by the plurality of detectors, the computing unit computing a feature value from the created image, and deriving, from the feature value, the amount of influence of charging of the surface of the sample on an electron beam trajectory or signal electron trajectories with respect to each position within a field of view.

### TECHNICAL FIELD

The present invention relates to a configuration and control of a charged particle beam device, and more particularly, to a technique effectively applied to inspection and measurement of a sample that is easily charged.

### BACKGROUND ART

Along with miniaturization and high integration of a semiconductor pattern, a slight difference in shape affects the operating characteristics of a device, and the need for shape management is increasing. Due to this fact, a scanning electron microscope (SEM) used for inspection and measurement of a semiconductor is required to have higher sensitivity and higher accuracy than those in the related art. A scanning electron microscope is a device that observes a sample by detecting electrons emitted from the sample, and can generate a signal waveform by detecting such electrons and measure, for example, a dimension between peaks (pattern edges).

In recent years, extreme ultraviolet (EUV) lithography has been introduced as a technique of forming a fine pattern of 10 nm or less on a wafer. In the EUV lithography, it has been found that a defect occurring randomly called a stochastic defect is a problem. Therefore, the need for inspection on the entire surface of the wafer is increasing, and an inspection device is required to have improved inspection accuracy and higher throughput.

As a background art of the present technical field, for example, there is a technique as disclosed in PTL 1. PTL 1 discloses a method of detecting an electric charge amount on a sample surface using a signal in a state (mirror state) in which primary electrons do not reach the sample.

In addition, PTL 2 discloses a method of clearly identifying a material or a shape of a sample surface even when a layer formed on the sample surface is thin and contrast of an observation image is difficult to obtain.

PTL 3 discloses a method of setting observation conditions of an electron microscope by irradiating a fixed position in an observation region with a pulsed intermittent electron beam and detecting a temporal change of electrons emitted from a sample due to the intermittent electron beam.

### CITATION LIST

### Patent Literature

PTL 1: JP2008-153085A
PTL 2: JP2021-39844A
PTL 3: JP2013-214467A

### SUMMARY OF INVENTION

### Technical Problem

In order to increase the inspection efficiency (throughput), it is conceivable to inspect a wide region at a time by low-magnification imaging using a large current.

However, when the sample is made of a material that is easily charged, the influence of charging appears remarkably in low-magnification observation, and in particular, trajectories of signal electrons generated from the sample are deflected. Accordingly, various phenomena that lower the inspection accuracy occur, such as image distortion, shading (luminance unevenness), and contrast abnormality.

Accordingly, in order to apply low-magnification imaging to a pattern formed of a material such as a resist that is easily charged, it is necessary to restrict the influence of a charging phenomenon on a signal electron trajectory.

In PTL 1, an average electric charge amount in the entire field of view can be estimated, but the distribution of the electric charge amount in the field of view is not mentioned. Further, PTL 1 does not mention derivation of a deflection amount of electrons.

In PTL 2, an electric charge amount can be derived based on the amount of electric charge removed by the photoelectric effect, but similarly to PTL 1, the distribution of the electric charge amount in a field of view cannot be measured.

In PTL 3, an acceleration voltage, a scanning speed, focus, astigmatism, and the like are described as observation conditions, but optimization of deflection of electron trajectory is not mentioned.

Therefore, an object of the invention is to provide a charged particle beam device capable of restricting an influence on an electron trajectory due to charging of a sample and achieving both high accuracy and high throughput, and an inspection method using the charged particle beam device.

### Solution to Problem

In order to solve the above problems, the invention provides a charged particle beam device including: a scanning deflector configured to perform scanning with an electron beam emitted from a charged particle source; a signal electron deflector configured to deflect trajectories of signal electrons emitted from a sample; a plurality of detectors configured to detect the signal electrons obtained based on the scanning performed with the electron beam; and a computing unit configured to create an image of the sample by using the signal electrons detected by the plurality of detectors. The computing unit calculates a feature based on the created image, and derives, based on the feature, an amount of influence for each position in a field of view that charging of a surface of the sample applies to an electron beam trajectory or the signal electron trajectories.

Further, the invention provides an inspection method using a charged particle beam device, the inspection method including the following steps: (a) a step of irradiating and scanning a sample with an electron beam emitted from a charged particle source; (b) a step of detecting signal electrons obtained based on the scanning performed with the electron beam; (c) a step of creating an image of the sample using the signal electrons detected in the step (b); and (d) a step of calculating a feature based on the image created in the step (c) and deriving, based on the feature, an amount of influence for each position in a field of view that charging of a surface of the sample applies to electron beam trajectories or signal electron trajectories.

### Advantageous Effects of Invention

According to the invention, it is possible to implement a charged particle beam device capable of restricting an influence on an electron trajectory due to charging of a sample and achieving both high accuracy and high throughput, and an inspection method using the charged particle beam device.

Accordingly, even in low-magnification observation using a large current, it is possible to restrict a decrease in inspection accuracy due to charging of the sample, and highly accurate and highly efficient inspection is possible.

Problems, configurations, and effects other than those described above will become apparent by description of the following embodiments.

### BRIEF DESCRIPTION OF DRAWINGS

FIG. 1 is a diagram illustrating a schematic configuration of a scanning electron microscope according to Embodiment 1 of the invention.

FIG. 2 is a diagram conceptually illustrating an influence of charging of a sample on a signal electron trajectory.

FIG. 3 is a diagram illustrating an example of a white spot image.

FIG. 4 is a flowchart illustrating a method of deriving a signal electron deflection amount and a deflection direction based on a white spot image according to Embodiment 1 of the invention.

FIG. 5 is a graph illustrating a relationship between a film thickness of a sample and a diameter of a white spot.

FIG. 6 is a diagram conceptually illustrating an influence of charging of a sample on a primary electron trajectory.

FIG. 7 is a flowchart illustrating a method of deriving a deflection amount and a deflection direction of a primary electron based on a magnification variation according to Embodiment 2 of the invention.

FIG. 8 is a graph illustrating a relationship between a filter voltage of an energy filter and luminance of an image.

### DESCRIPTION OF EMBODIMENTS

Hereinafter, embodiments of the invention will be described with reference to the drawings. In the drawings, the same components are denoted by the same reference signs, and a detailed description of the repeating components is omitted.

### Embodiment 1

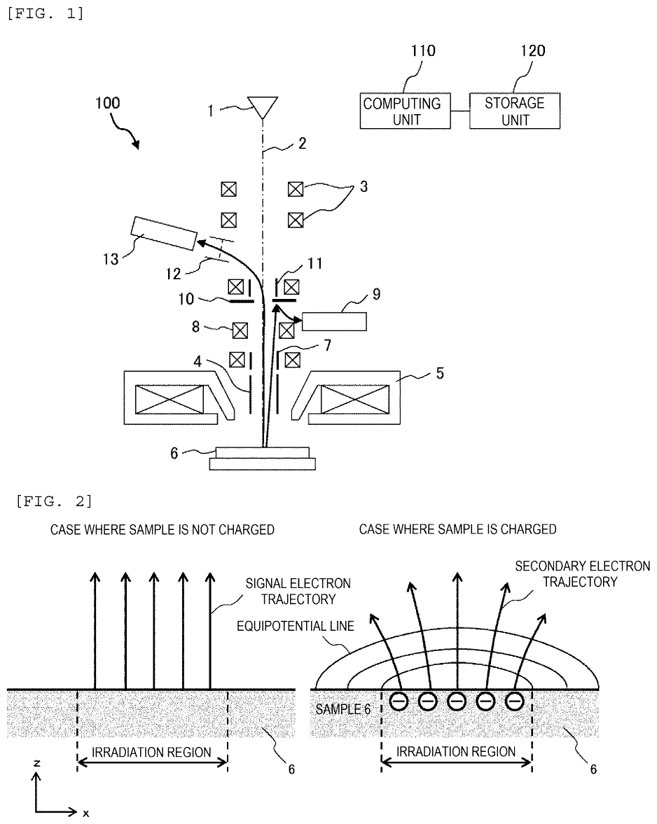

A charged particle beam device and an inspection method using the charged particle beam device according to Embodiment 1 of the invention will be described with reference to FIGS. 1 to 5 and 8.

FIG. 1 is a diagram illustrating a schematic configuration of a scanning electron microscope (SEM) 100 that is a charged particle beam device of the embodiment.

As illustrated in FIG. 1, the scanning electron microscope 100 of the embodiment includes, as main components, an electron gun 1, a condenser lens 3, a deflector (scanning deflector) 4, an objective lens 5, a signal electron deflector 7, a condenser lens (divergence angle adjustment lens) 8, a detector 9, a signal electron diaphragm 10, a signal electron deflector 11, a detector 13, a computing unit 110, and a storage unit 120.

An electron beam (primary electron beam) 2 generated by the electron gun 1 is converged by the condenser lens 3, and is converged and irradiated onto a sample 6 by the objective lens 5. At this time, a divergence angle of the electron beam (primary electron beam) 2 can be adjusted by the condenser lens (divergence angle adjustment lens) 8.

With the deflector (scanning deflector) 4, an electron beam scanning region of the sample 6 is scanned with the electron beam (primary electron beam) 2. By irradiating and two-dimensionally scanning the sample 6 with the electron beam (primary electron beam) 2, signal electrons excited in the sample 6 and emitted from the sample 6 are detected by the detector 9 and the detector 13, and a detection signal is converted into an image by the computing unit 110, thereby acquiring an observation image of the sample 6.

Through the signal electron deflector 7, signal electrons emitted from the sample 6 are divided into electrons passing through the signal electron diaphragm 10 and electrons colliding with the signal electron diaphragm 10. The electrons colliding with the signal electron diaphragm 10 generate tertiary electrons, and the tertiary electrons are detected by the detector 9.

The electrons passing through the signal electron diaphragm 10 are deflected toward the detector 13 through the signal electron deflector 11, and are detected by the detector 13.

As illustrated in FIG. 1, in a part of the scanning electron microscope, an energy filter 12 capable of discriminating the signal electrons by energy is provided upstream of the detector 13, and the detector 13 detects electrons passing through the energy filter 12. A charged state of the sample 6 can be estimated based on a change in signal amount at the time when a voltage applied to the energy filter 12 is changed.

However, charge measurement by the energy filter 12 has a problem of taking time, and is not realistic in aiming at high throughput measurement of 1 cm²/hr or more in the future.

The computing unit 110 performs control of each optical element provided in the scanning electron microscope 100, control of the voltage applied to the energy filter 12, control of a deflection amount of the signal electron deflector 7, calculation of a synthesis ratio of signals detected by the detector 9 and the detector 13, and the like. The computing unit 110 creates the observation image of the sample 6 using the detection signals of the signal electrons detected by the detectors 9 and 13.

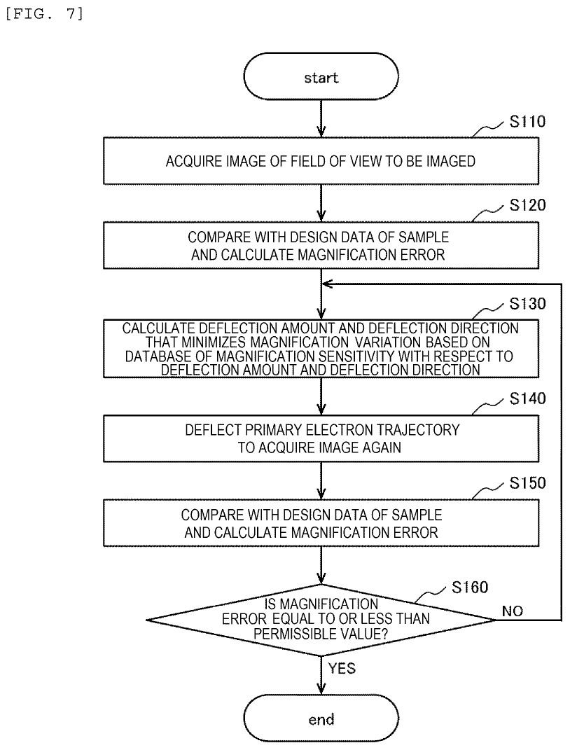

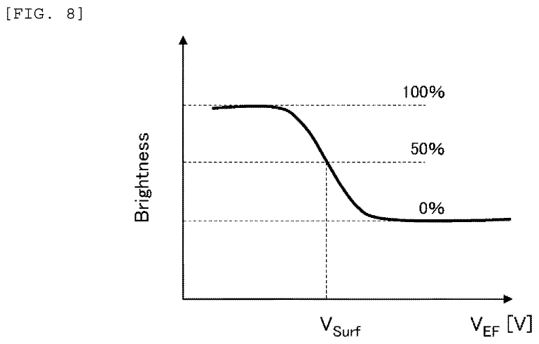

The storage unit 120 is a storage device that stores data used by the computing unit 110. For example, a luminance profile of a reference image, an image sensitivity database with respect to a deflection amount, and the like, which will be described later with reference to FIGS. 4 and 7, can be stored.

The scanning electron microscope 100 includes, in the storage unit 120 or the like, an image memory that stores a detection signal for each pixel, and the detection signal is stored in the image memory.

The computing unit 110 calculates a signal waveform of a designated region in an image based on image data stored in the image memory. The computing unit 110 estimates a charged state in a field of view based on the image, and in order to control the charged state, changes deflection amounts of the primary electrons and the signal electrons and the synthesis ratio of the signals of the detectors 9 and 13 based on the obtained estimated state.

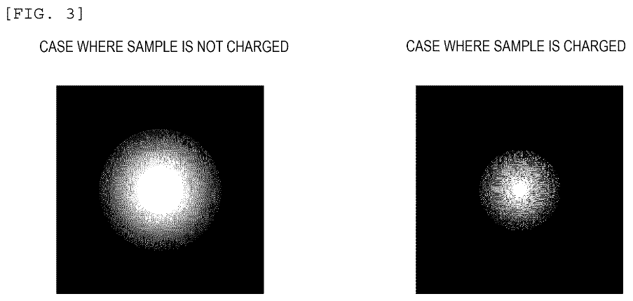

FIG. 2 is a diagram conceptually illustrating an influence of charging of a sample on a signal electron trajectory. A left part of FIG. 2 illustrates a case where the sample 6 is not charged, and a right part of FIG. 2 schematically illustrates potential distribution and signal electron trajectories in a case where the sample 6 is negatively charged.

As illustrated in the right part of FIG. 2, when the sample 6 is charged by the irradiation of the electron beam (primary electron beam) 2, a potential difference is generated on a surface of the sample 6 to function as a lens, and signal electron trajectories (secondary electron trajectories) are bent.

Here, it is assumed that the signal electrons are emitted from the sample 6 upward in a vertical direction (upward in a z direction in FIG. 2). At this time, at ends of an irradiation region, since a gradient of potential has a horizontal direction (x direction in FIG. 2) component, the signal electron trajectory is bent in the horizontal direction. Accordingly, a phenomenon such as image distortion that deteriorates the inspection accuracy occurs.

Further, in the right part of FIG. 2, although a case is assumed where the surface is uniformly charged in the irradiation region, in a case where charge distribution is uneven, the signal electron trajectory is affected since the gradient of the potential has a horizontal direction component. If a deflection amount of the signal electron trajectory (secondary electron trajectory) due to the charging of the sample 6 can be estimated and the signal electron trajectory can be deflected so as to cancel the deflection amount, the influence of the charging on the signal electrons can be eliminated.

Therefore, in the embodiment, the deflection amount of the signal electron trajectory is estimated using an image called a “white spot”.

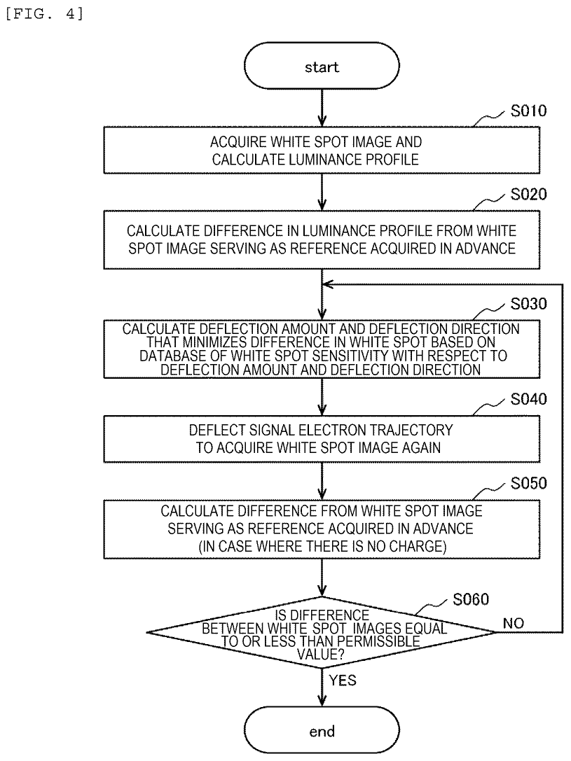

FIG. 3 illustrates an example of a white spot image. A left part of FIG. 3 shows a white spot in the case where the sample 6 is not charged, and a right part of FIG. 3 shows a white spot in the case where the sample 6 is charged.

As illustrated in FIG. 1, the scanning electron microscope 100 of the embodiment includes two detectors (reference numerals 9 and 13), and an image generated only from the signal electrons passing through the signal electron diaphragm 10 and reaching the detector 13 is called a “white spot”, which is an image as shown in FIG. 3.

As illustrated in the left part of FIG. 3, in a state where the sample 6 is not charged, the white spot is substantially circular and occurs at the center of a field of view. On the other hand, as illustrated in the right part of FIG. 3, when a charging level of the sample 6 increases, a size (diameter) of the white spot changes. In addition, when the charging is not uniform, a position of the center is deviated or the shape is not a clean circle.

When the surface of the sample 6 is charged, the signal electron trajectories are bent as illustrated in the right part of FIG. 2. Accordingly, the amount of signal electrons passing through the signal electron diaphragm 10 changes, and the size of the white spot changes. Here, information on a white spot in a state where the sample is not charged is stored in the storage unit 120 in advance and a white spot obtained in a state where the sample is charged is compared with the information, whereby an electric charge amount of the sample 6 can be estimated.

Further, by changing a deflection direction and a deflection amount of the signal electron deflector 11 for each irradiation position of the electron beam (primary electron beam) 2 onto the sample 6 so that the size (diameter) of the white spot, the position of the center, and the shape of the white spot are close to the reference white spot, it is possible to cancel out the influence on the signal electrons due to charging.

FIG. 4 illustrates a method of deriving a deflection amount and a deflection direction of a signal electron based on a white spot image in the embodiment.

First, in step S010, a white spot image of an imaging object (sample 6) is acquired, and a luminance profile thereof is calculated.

Next, in step S020, a luminance profile of a white spot image (image acquired in a state where the sample is not charged) as a reference acquired in advance is calculated, and a difference from the profile calculated in step S010 is calculated.

Subsequently, in step S030, with reference to a white spot sensitivity database with respect to the deflection amount and the deflection direction of the signal electron acquired in advance, the deflection amount and the deflection direction that minimize the difference between the white spots are calculated for each position in the field of view.

This database is created in advance by measuring or predicting through simulation a change in the luminance profile with respect to a change in the deflection amount and the deflection direction.

Next, in step S040, a white spot image is acquired again by applying the deflection amount and the deflection direction calculated in step S030.

Subsequently, in step S050, a difference from the reference white spot image is calculated again.

Finally, in step S060, it is determined whether the difference is equal to or less than a preset permissible value. When the difference is equal to or less than the permissible value (YES), identification of the deflection amount and the deflection direction of the signal electron trajectory is completed.

On the other hand, when the difference is greater than the permissible value (NO), the process returns to step S030, and the deflection amount and the deflection direction are calculated again so that the difference between the white spots is minimized. The processing of steps S030 to S060 is repeated, and when the difference is equal to or less than the permissible value, the identification of the deflection amount and the deflection direction of the signal electron trajectory is completed.

Although the case where the electric charge amount on the surface of the sample 6 is substantially uniform is assumed and described above, it is possible to identify the deflection amount and the deflection direction of the signal electron by the above-described method even when the center of the white spot image is deviated from the center of the field of view, the white spot is distorted and the white spot is not a clear circle due to uneven charging.

Further, when it may be assumed that the charge distribution on the surface of the sample 6 is substantially uniform, an average electric charge amount of the sample surface may be estimated based on, in addition to the white spot image, a relationship (S-curve shaped curve) between a filter voltage of the energy filter 12 and the amount of signal electrons passing through the energy filter 12 (luminance profile of the image) as shown in FIG. 8, and the deflection amount and the deflection direction of the signal electrons may be calculated based on the estimated average electric charge amount.

In general, in the process of charge accumulation, unevenness in charge distribution occurs on the sample surface, and the charged state changes with time. When a certain period of time elapses, the charging is saturated and uniform charging occurs in the irradiation region. While the charged state is changing, stable imaging is difficult, and the accuracy in estimating the amount of influence due to charging also decreases.

Accordingly, by observing the shape of the white spot reflecting the charged state, an electron beam irradiation time when the shape of the white spot does not change with time is calculated as a charging saturation time, and by feeding back to an imaging condition, it is possible to perform imaging in a state in which the charging is stable and saturated.

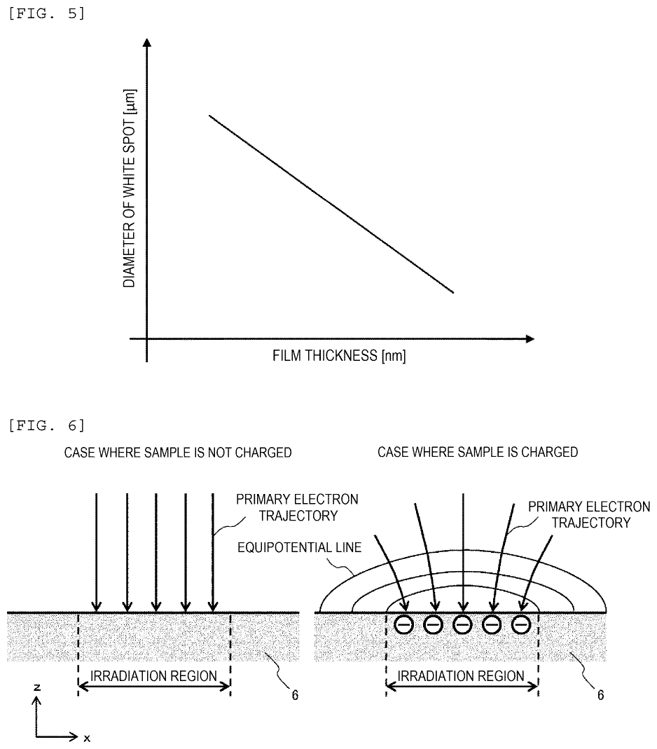

It is also possible to identify a film thickness of the sample 6 based on the size (diameter) of the white spot. The ease of charge loss of the sample depends on the film thickness of the sample, and the size (diameter) of the white spot decreases as the film thickness of the sample increases. Therefore, by acquiring in advance the relationship between the size (diameter) of the white spot and the film thickness as illustrated in FIG. 5, it is possible to estimate the film thickness of the sample based on the size (diameter) of the white spot.

### Embodiment 2

A charged particle beam device and an inspection method using the charged particle beam device according to Embodiment 2 of the invention will be described with reference to FIGS. 6 and 7.

In Embodiment 1, the method of calculating the influence of the charging of the sample surface on the signal electron trajectory and correcting the signal electron trajectory based on the influence is described. In the present embodiment, a method of calculating an influence of charging of a sample surface on a primary electron trajectory, which is exerted before electrons reach a sample, and correcting the primary electron trajectory based on the influence will be described. The configuration of the scanning electron microscope 100 is the same as that of Embodiment 1 (FIG. 1).

FIG. 6 is a diagram conceptually illustrating the influence of charging of a sample on a primary electron trajectory. A left part of FIG. 6 illustrates a case where the sample 6 is not charged, and a right part of FIG. 6 schematically illustrates potential distribution and primary electron trajectories in a case where the sample 6 is negatively charged.

As illustrated in the right part of FIG. 6, when the sample 6 is charged by irradiation of the electron beam (primary electron beam) 2, a potential difference is generated on a surface of the sample 6 to function as a lens, and the primary electron trajectories are bent similarly to the case of the signal electron trajectories illustrated in FIG. 2.

Here, it is assumed that the primary electrons are irradiated to the sample 6 in a vertical direction (a lower side in a z direction in FIG. 6). At this time, in the vicinity of a center of an irradiation region, since a gradient of potential does not have a horizontal direction (x direction in FIG. 6) component, the primary electron trajectory is not bent.

On the other hand, at ends of the irradiation region, since the gradient of potential has a horizontal direction (x direction in FIG. 6) component, the primary electron trajectory is bent in the horizontal direction. Accordingly, a phenomenon such as a magnification error that deteriorates the inspection accuracy occurs.

Further, in the right part of FIG. 6, although a case is assumed where the surface is uniformly charged in the irradiation region, in a case where charge distribution is uneven, the primary electron trajectory is affected since the gradient of the potential has a horizontal direction component. If a deflection amount of the primary electron trajectory due to charging of the sample 6 can be estimated and the primary electron trajectory can be deflected so as to cancel the deflection amount, the influence of charging on the primary electron trajectory, that is, the electron beam (primary electron beam) 2 can be eliminated.

FIG. 7 illustrates a method of deriving the deflection amount and the deflection direction of the primary electron based on a magnification variation of the embodiment.

First, in step S110, an image of a field of view to be imaged (sample 6) is acquired.

Next, in step S120, a magnification error in the field of view is calculated by comparison with design data of the sample 6 acquired in advance. Based on distribution of the magnification error, the charge distribution on the surface of the sample 6 can also be estimated.

Subsequently, in step S130, the deflection amount and the deflection direction of the primary electron that minimize the magnification error are calculated with reference to a magnification variation database for the deflection amount and the deflection direction of the primary electron acquired in advance.

This database is created in advance by measuring or predicting through simulation a change in the magnification with respect to a change in the deflection amount and the deflection direction.

Next, in step S140, an image is acquired again by applying the deflection amount and the deflection direction calculated in step S130.

Subsequently, in step S150, the magnification error is calculated again by comparison with the design data of the sample 6.

Finally, in step S160, it is determined whether the magnification error is equal to or less than a preset permissible value. When the magnification error is equal to or less than the permissible value (YES), identification of the deflection amount and the deflection direction of the primary electron trajectory is completed.

On the other hand, when the magnification error is greater than the permissible value (NO), the process returns to step S130, and the deflection amount and the deflection direction are calculated again so that the magnification error is minimized. The processing of steps S130 to S160 is repeated, and when the magnification error is equal to or less than the permissible value, the identification of the deflection amount and the deflection direction of the primary electron trajectory is completed.

As a scanning method of the electron beam (primary electron beam) 2, there are a scanning method (TV scan) in which scanning is performed line by line in order and a scanning method (Flat scan) in which scanning is performed while dividing a field of view at equal intervals. In the embodiment, the method of optimizing the deflection amount and the deflection direction of the primary electron trajectory is described, and a similar reduction in the magnification variation can be achieved by the optimization of the scanning method of primary electrons.

### Embodiment 3

A charged particle beam device and an inspection method using the charged particle beam device according to Embodiment 3 of the invention will be described.

In the embodiment, a method of correcting an influence of charging of the sample 6 by correcting a captured image without correcting an electron trajectory will be described. The configuration of the scanning electron microscope 100 is the same as that of Embodiment 1 (FIG. 1).

In Embodiment 1, it is described that a diameter of a white spot changes due to charging of the sample 6, and this means that a ratio between the signal electron passing through the signal electron diaphragm 10 and detected by the detector 13 and the signal electron colliding with the signal electron diaphragm 10 to generate a tertiary electron detected by the detector 9 changes.

When an electron microscope in the related art includes a plurality of detectors as described above, images generated based on signals detected by the respective detectors are synthesized uniformly within a field of view at a certain ratio.

Here, if the synthesis ratio is set to an optimum value for each position in the field of view, the image can be made close to an image without charging.

Specifically, the ratio of the signal electrons detected by the detector 9 and the detector 13 is calculated based on the white spot image, and a synthesis ratio of the image of each detector is determined so as to be the same as that in the case where the sample is not charged. Accordingly, the influence of charging can be reduced by image processing without deflecting the electron trajectory.

In each of the above embodiments, the scanning electron microscope (SEM) has been described as an example of the charged particle beam device, and the invention is not limited thereto. The invention can also be applied to another charged particle beam device that acquires an observation image of a sample by irradiation of a charged particle beam.

The invention is not limited to the above-described embodiments, and includes various modifications. For example, the embodiments described above have been described in detail to facilitate understanding of the invention, and the invention is not necessarily limited to those including all the configurations described above. A part of a configuration according to one embodiment can be replaced with a configuration according to another embodiment, and a configuration according to one embodiment can also be added to a configuration according to another embodiment. A part of a configuration according to each embodiment may be added, deleted, or replaced with another configuration.

### REFERENCE SIGNS LIST

1: ELECTRON GUN
2: ELECTRON BEAM (PRIMARY ELECTRON BEAM)
3: CONDENSER LENS
4: DEFLECTOR (SCANNING DEFLECTOR)
5: OBJECTIVE LENS
6: SAMPLE
7: SIGNAL ELECTRON DEFLECTOR
8: CONDENSER LENS (DIVERGENCE ANGLE ADJUSTMENT LENS)
9: DETECTOR
10: SIGNAL ELECTRON DIAPHRAGM
11: SIGNAL ELECTRON DEFLECTOR
12: ENERGY FILTER
13: DETECTOR
100: SCANNING ELECTRON MICROSCOPE (SEM)
110: COMPUTING UNIT
120: STORAGE UNIT
V_{EF}: VOLTAGE OF ENERGY FILTER
V_{Surf}: SAMPLE SURFACE VOLTAGE

1. A charged particle beam device comprising:
a scanning deflector configured to perform scanning with an electron beam emitted from a charged particle source;
a signal electron deflector configured to deflect trajectories of signal electrons emitted from a sample;
a plurality of detectors configured to detect the signal electrons obtained based on the scanning performed with the electron beam; and
a computing unit configured to create an image of the sample by using the signal electrons detected by the plurality of detectors, wherein
the computing unit calculates a feature based on the created image, and derives, based on the feature, an amount of influence for each position in a field of view that charging of a surface of the sample applies to an electron beam trajectory or the signal electron trajectories.

2. The charged particle beam device according to claim 1, wherein
the amount of influence is a deflection amount of the signal electron trajectories.

3. The charged particle beam device according to claim 2, further comprising:
a signal electron diaphragm configured to discriminate the signal electrons reaching the detector, wherein
the feature is calculated based on a white spot image obtained based on the signal electrons passing through the signal electron diaphragm.

4. The charged particle beam device according to claim 2, further comprising:
an energy filter configured to discriminate the signal electrons, which reach the detector, by energy, wherein
the feature is calculated based on a relationship between a filter voltage of the energy filter and luminance of the image.

5. The charged particle beam device according to claim 2, wherein
a correction amount is determined based on the amount of influence, and the signal electron trajectories are corrected based on the correction amount.

6. The charged particle beam device according to claim 1, wherein
an electric charge amount of the sample surface is obtained based on the feature.

7. The charged particle beam device according to claim 1, wherein
a charge saturation time of the sample is obtained based on a temporal change of the feature.

8. The charged particle beam device according to claim 1, wherein
a film thickness of the sample is obtained based on the feature.

9. The charged particle beam device according to claim 1, wherein
the amount of influence is a deflection amount of the electron beam trajectories.

10. The charged particle beam device according to claim 9, wherein
the feature is calculated based on a magnification variation in a field of view with respect to a deflection amount of the electron beam acquired in advance.

11. The charged particle beam device according to claim 1, wherein
the amount of influence is determined by a method of scanning with the electron beam.

12. The charged particle beam device according to claim 1, wherein
a correction amount is determined based on the amount of influence, and the image of the sample is corrected based on the correction amount.

13. The charged particle beam device according to claim 12, wherein
the correction amount is determined based on a synthesis ratio of the image of the sample created using the signal electrons detected by the plurality of detectors.

14. An inspection method using a charged particle beam device, the inspection method comprising the following steps:
(a) a step of irradiating and scanning a sample with an electron beam emitted from a charged particle source;
(b) a step of detecting signal electrons obtained based on the scanning performed with the electron beam;
(c) a step of creating an image of the sample using the signal electrons detected in the step (b); and
(d) a step of calculating a feature based on the image created in the step (c) and deriving, based on the feature, an amount of influence for each position in a field of view that charging of a surface of the sample applies to electron beam trajectories or signal electron trajectories.

15. The inspection method using a charged particle beam device according to claim 14, wherein
the feature is calculated based on a white spot image obtained based on the signal electrons passing through a signal electron diaphragm.
